(19) United States
(12) Patent Application Publication
(10) Pub. No.: US 2019/0204701 A1
(43) Pub. Date: Jul. 4, 2019

(54) DISPLAY PANEL AND DISPLAY DEVICE

(71) Applicants: BOE TECHNOLOGY GROUP CO., LTD., Beijing (CN); BEIJING BOE OPTOELECTRONICS TECHNOLOGY CO., LTD., Beijing (CN)

(72) Inventors: Yanqiang WANG, Beijing (CN); Liangjie LI, Beijing (CN); Hao DONG, Beijing (CN)

(21) Appl. No.: 16/329,017

(22) PCT Filed: May 15, 2018
(86) PCT No.: PCT/CN2018/086825

§ 371 Date: Feb. 27, 2019

(30) Foreign Application Priority Data
Jun. 13, 2017 (CN) 201710442914.7

(51) Int. Cl. G02F 1/1362; G02F 1/1368; H01L 31/0288; H01L 31/105

(52) U.S. Cl. CPC G02F 1/136286; G02F 1/1368; G02F 2001/13312; H01L 31/105; G02F 2001/136222; H01L 31/0288

(57) ABSTRACT

The present application provides a display panel and a display device. The display panel is divided into a plurality of pixel regions, a thin film transistor is disposed in a pixel region of the plurality of pixel regions, and a gate line and a data line intersect between adjacent ones of the plurality of pixel regions. A photodiode is provided in at least one of an area corresponding to the thin film transistor in the pixel region, an area corresponding to the gate line, or an area corresponding to the data line, and the photodiode is electrically connected to the gate line or the data line.

### CROSS-REFERENCE TO RELATED APPLICATION

This is a National Phase Application filed under 35 U.S.C. 371 as a national stage of PCT/CN2018/086825, filed on May 15, 2018, an application claiming the benefit of Chinese Patent Application No. 201710442914.7, filed on Jun. 13, 2017, the entire contents of which are hereby incorporated by reference.

### TECHNICAL FIELD

The present disclosure relates to the field of display technology, and particularly, relates to a display panel and a display device.

### BACKGROUND

With the development of science and technology, flat panel display devices have replaced cumbersome CRT display devices in people's daily lives. Commonly used flat panel display devices include liquid crystal display devices (LCDs).

The liquid crystal display device includes a backlight, and further includes a color filter substrate and an array substrate disposed opposite to each other, and a liquid crystal layer disposed therebetween. Each pixel of the array substrate is provided with a thin film transistor (TFT) for controlling the deflection of the liquid crystal molecules in the liquid crystal layer, thereby allowing the light of the backlight to selectively transmit, and the transmitted light forms an image display through colorization of a color film layer in the color filter substrate.

### SUMMARY

An embodiment of the present disclosure provides a display panel having a plurality of pixel regions, a thin film transistor being disposed in a pixel region of the plurality of pixel regions, a gate line and a data line intersecting between adjacent ones of the plurality of pixel regions, wherein a photodiode is provided in at least one of an area corresponding to the thin film transistor in the pixel region, an area corresponding to the gate line, or an area corresponding to the data line, and the photodiode is electrically connected to either the gate line or the data line.

In an embodiment, the photodiode includes a forward electrode, a P layer, an I layer, an N layer, and a reverse electrode which are sequentially stacked, the reverse electrode is connected to the gate line or the data line, and the forward electrode is connected a low voltage terminal.

In an embodiment, the display panel includes an array substrate, the thin film transistor is provided in the array substrate, the thin film transistor includes a gate, a gate insulating layer, an active layer, a source and a drain, the gate is connected to the gate line, and the source is connected to the data line, wherein the photodiode is disposed under the gate, and the gate is shared as the reverse electrode of the photodiode; alternatively, the photodiode is disposed under the source, and the source is shared as the reverse electrode of the photodiode.

In an embodiment, the display panel includes a color filter substrate, the photodiode is provided in an area corresponding to the thin film transistor in the pixel region in at least part of the color filter substrate, the reverse electrode of the photodiode is connected to the gate line or the data line through a connection medium, and the forward electrode is connected to a low voltage terminal.

In an embodiment, the connection medium is a gold ball or a silver ball.

In an embodiment, the forward electrode is made of a transparent metal material, and the transparent metal material comprises indium tin oxide.

In an embodiment, in the photodiode, the P layer is made of a B₂H₆ doped a-Si material, the I layer is made of an a-Si material, and the N layer is made of a PH₃ doped a-Si material.

In an embodiment, the forward electrode is grounded or is not loaded with any voltage, and the reverse electrode has a same voltage potential as a voltage potential of the gate line or the data line.

In an embodiment, the display panel further includes a backlight, and the forward electrode of the photodiode is closer to the backlight than the reverse electrode.

An embodiment of the present disclosure further provides a display device, which includes any of the above display panels.

### BRIEF DESCRIPTION OF THE DRAWINGS

FIG. 1 is a cross-sectional view of a display panel in a first embodiment of the present disclosure;

FIG. 2 is a cross-sectional view of a photodiode in FIG. 1;

FIGS. 3A to 3F are diagrams showing fabrication process of a display panel in the first embodiment of the present disclosure;

in which:

FIG. 3A is a cross-sectional view showing material film layers forming structural layers;

FIG. 3B is a cross-sectional view showing a structure obtained after an exposure process and a development process in a process of fabricating a photodiode;

FIG. 3C is a cross-sectional view showing a structure obtained after an ashing process in the process of fabricating the photodiode;

FIG. 3D is a cross-sectional view showing a structure obtained after an etching process in the process of fabricating the photodiode;

FIG. 3E is a cross-sectional view showing a structure obtained after forming an insulating protective layer;

FIG. 3F is a cross-sectional view showing a structure obtained after forming an overall structure of a thin film transistor;

### REFERENCE NUMERALS

1—substrate; 2—forward electrode; 20—transparent electrode film layer; 3—P layer; 30—P film layer; 4—I layer; 40—I film layer; 5—N layer; 50—N film layer; 6—gate; 60—gate film layer; 7—reverse electrode; 8—insulating protective layer; 9—active layer; 10—source; 11—drain; 12—photoresist.

### DETAILED DESCRIPTION

In order to enable those skilled in the art to better understand the technical solutions of the present invention, the display panel and the display device of the present disclosure are further described in detail below with reference to the accompanying drawings and specific embodiments.

As used herein, the expression of “at least one of A, B, and (or) C” or similar expressions refers to that there exists one or more A, and/or, one or more B, and/or, one or more C, and/or, any combination thereof.

With the advancement of the times, full high definition (FHD) display screens have gradually dominated, and FHD display screens have increased number of pixels, and the numbers of gate lines and data lines between pixels have increased in multiples. Line widths of the gate line and the data line become narrower to ensure proper transmittance, and the light utilization ratio is low, resulting in a low on-current Ion of the thin film transistor, an increase in power consumption, a slow response speed, and possibly further resulting in a phenomenon that the display panel product is blackening at the end of a scanning line due to insufficient charging.

Designing a display device with low power consumption and high light utilization ratio has always been a goal that technical engineers are striving for.

### First Embodiment

In view of the problems of low light utilization ratio and high power consumption due to the increased number of pixels in existing FHD liquid crystal display devices, the present embodiment provides a display panel, by setting a photodiode inside the display panel, not only power consumption and response time are effectively reduced, but also the phenomenon that the FHD liquid crystal display device is blackening at the end of a scanning line due to insufficient charging can be solved, thereby improving the utilization ratio of the backlight.

The display panel is divided into a plurality of pixel regions, a thin film transistor is disposed in a pixel region of the plurality of pixel regions, and a gate line and a data line intersect between adjacent ones of the plurality of pixel regions, wherein a photodiode is provided in at least one of an area corresponding to the thin film transistor in the pixel region, an area corresponding to the gate line, and an area corresponding to the data line, and the photodiode is electrically connected to either the gate line or the data line. In this way, some photodiode is connected to the gate line, and some photodiode is connected to the data line, so that all gate lines or data lines, or part of the gate lines or data lines in the display panel can be respectively connected to the photodiodes, thereby utilizing a weak current generated by photo-generated carriers of the photodiode to assist in driving the gate line or the data line, lowering the power consumption, and reducing the response time as well. The phenomenon that the FHD liquid crystal display device is blackening at the end of a scanning line due to insufficient charging can be solved as well.

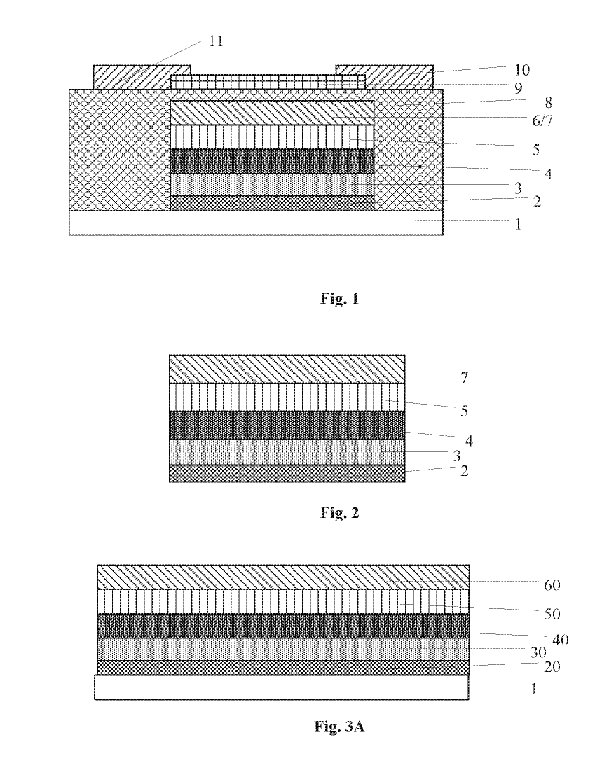

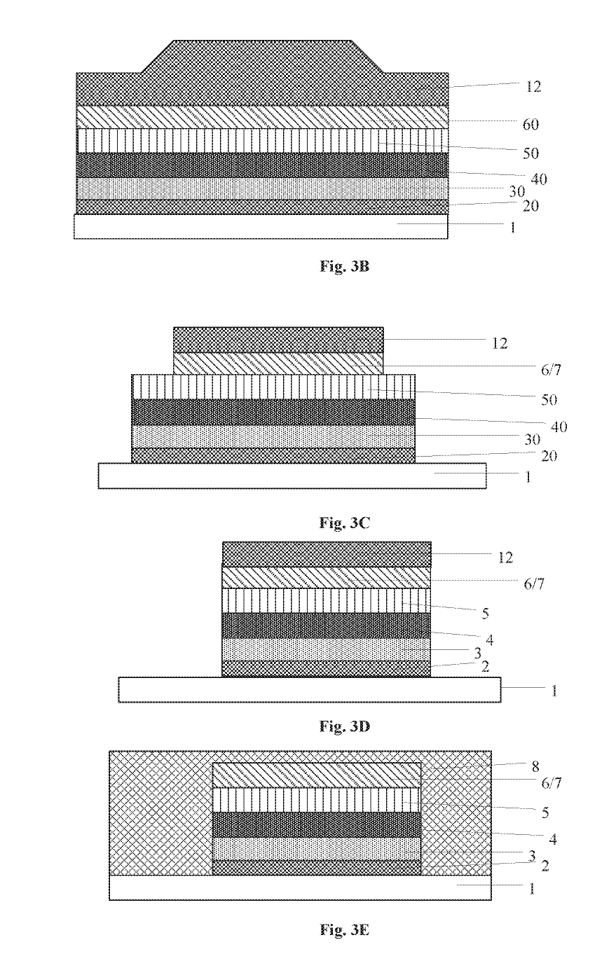

As shown in FIG. 1, the display panel includes an array substrate. The array substrate is provided with a thin film transistor in each pixel region. The thin film transistor includes a gate 6, a gate insulating layer (i.e., an insulating protective layer 8 in FIG. 1), an active layer 9, a source 10 and a drain 11, which are disposed on a substrate 1. The gate 6 is connected to the gate line, and the source 10 is connected to the data line (the gate line and the data line are not shown in FIG. 1). Generally, the gate line and the data line are disposed in the array substrate, the gate line is configured to provide a scan signal for the thin film transistor, and the data line is configured to provide a data signal for the thin film transistor. The drain 11 of the thin film transistor provides a corresponding driving voltage based on the data signal when the thin film transistor is turned on by scanning, thereby realizing image display. In FIG. 2, the photodiode includes a forward electrode 2, a P layer 3, an I layer 4, an N layer 5, and a reverse electrode 7 which are sequentially stacked. The reverse electrode 7 is connected to the gate line or the data line, and the forward electrode 2 is connected a low voltage terminal. In the photodiode, the P layer 3 is formed of a B₂H₆ doped a-Si material, the I layer 4 is formed of an a-Si material, and the N layer 5 is formed of a PH₃ doped a-Si material.

In the array substrate shown in FIG. 1, the photodiode is disposed in an area corresponding to the thin film transistor in the pixel region, the photodiode is disposed under the gate 6, and the gate 6 is also shared as the reverse electrode 7 of the photodiode; alternatively, the photodiode is disposed under the source 10, and the source 10 is also shared as the reverse electrode 7 of the photodiode. By sharing the electrodes of the photodiode partially with the thin film transistor, not only the structure of the array substrate is simplified to a certain extent, but also the fabrication process is simplified, while using the weak current generated by photo-generated carriers to assist operations of the gate line and/or the data line. Needless to say, the photodiode may also be disposed under the area corresponding to the gate line or under the area corresponding to the data line, and the structure thereof will not be described.

The display panel may be a liquid crystal display, and the display panel further includes a backlight (not shown in FIG. 1), and the forward electrode 2 of the photodiode is closer to the backlight than the reverse electrode 7. The liquid crystal itself does not emit light, and the backlight provides a light source for the photodiode while providing a light source for image display, so that the photodiode generates a photo-generated current, thereby improving the light utilization ratio.

The forward electrode 2 is formed of a transparent metal material, and the transparent metal material includes Indium Tin Oxide (ITO). The transparent nature of the forward electrode 2 ensures its effective receipt and utilization of the light source, and ensures that the light source illuminates the structural layer of the photodiode away from the backlight.

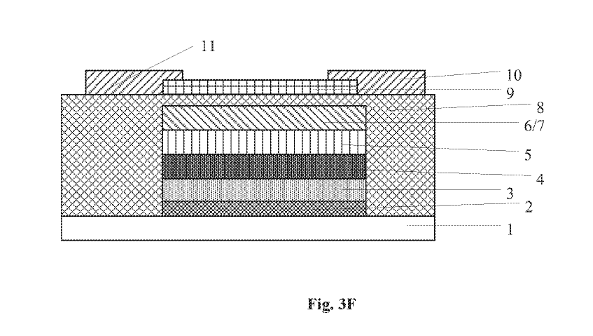

The fabrication process of the display panel is shown in FIG. 3A to FIG. 3F.

In FIG. 3A, material film layers of structural layers are formed. In an embodiment, a transparent electrode film layer 20 is formed on the substrate 1, the transparent electrode film layer 20 being formed of an ITO material; a P film layer 30 is formed on the transparent electrode film layer 20, the P film layer 30 being formed of a B₂H₆ doped a-Si material; an I film layer 40 is formed on the P film layer 30, the I film layer 40 being formed of an a-Si material; an N film layer 50 is formed on the I film layer 40, the N film layer 50 being formed of a PH₃ doped a-Si material, and these three layers of the P film layer 30, the I film layer 40 and the N film layer 50 may be formed in a single coating process; and next, a gate film layer 60 is formed on the N film layer 50.

In FIG. 3B, in the process of forming a pattern of a gate, in order to avoid corrosion of the gate metal in the gate film layer 60 during subsequent dry etching process, the adopted mask is a gray scale mask or a halftone mask, the gate film layer 60 is protected by forming a photoresist 12 with different thickness, and a wet etching process is performed on the gate film layer 60 to form the gate 6. After that, as shown in FIG. 3C, an ashing process is performed, and then a dry etching process is performed on the three layers of the P film layer 30, the I film layer 40 and the N film layer 50 to form a PIN junction of a photodiode. Finally, a wet etching process is performed on the transparent electrode film layer 20 on the bottom to form the forward electrode 2, and the structure after the etching process is completed is shown in FIG. 3D.

In FIG. 3E, the insulating protective layer 8 is formed using a transparent organic resin material or silicon nitride.

In FIG. 3F, the active layer 9 is formed on the insulating protective layer 8 using an a-Si material, and then the source 10 and the drain 11 are formed. Finally, a pixel electrode is formed, and thus, the fabrication of the display panel is completed.

Taking a case in which the photodiode is disposed under the gate 6 as an example, the principle of lowering the power consumption of the thin film transistor and therefore lowering the power consumption of the display panel by means of the photodiode in the display panel of the present embodiment lies in that the photodiode is operated under a reverse biased condition with the N layer 5 of the photodiode being disposed under the gate 6 and having a same voltage potential as that of the gate 6 and the other end of the photodiode being grounded (which may be connected to the ground line of the flexible printed circuit, FPC) or being not loaded with any voltage; and in this case, a portion of the light from the backlight which is blocked by the gate 6 can irradiate onto the photodiode to generate a photo-generated current, which is not large enough to turn on the thin-film transistor, but can assist in turning on the thin film transistor due to the compensation by the weak current when the gate 2 is scanned to turn on the thin film transistor during progressive scanning. As such, the response time is reduced, the power consumption is reduced, and the utilization ratio of the backlight is improved.

In a case where the photodiode is disposed under the source 10, a portion of the light from the backlight which is blocked by the source 10 or the data line can irradiate onto the photodiode to generate a photo-generated current for compensating for the data line with the weak current when the data line is transmitting data. Similarly, when the photodiode is disposed under the gate line or the data line, the weak current compensation can also be performed on the gate line or the data line, which will not be described in detail here.

In view of the problems of high power consumption, low on-current Ion and low light utilization ratio in existing products, the display panel of the present embodiment has a PIN junction of a photodiode structure fabricated under the gate, the source, the gate line or the data line of the array substrate, and the weak current generated by the PIN junction is used to assist the turning-on of the thin film transistor, thereby improving the response speed of the display panel, reducing the power consumption of the display panel, and solving the phenomenon that the display panel product is blackening at the end of a scanning line. The display panel of the present embodiment is especially suitable for the FHD liquid crystal display products.

### Second Embodiment

In view of the problems of low light utilization ratio and high power consumption due to the increased number of pixels in existing FHD liquid crystal display devices, the present embodiment provides a display panel, which effectively reduces power consumption, reduces response time and improves the utilization ratio of the backlight by setting a photodiode inside the display panel, and further solves the phenomenon that the FHD liquid crystal display device is blackening at the end of a scanning line due to insufficient charging.

The display panel includes a color filter substrate. The present embodiment differs from the first embodiment in that the structure of the photodiode is disposed in the color filter substrate.

In the display panel of the present embodiment, the photodiode is disposed in an area corresponding to the thin film transistor in the pixel region in at least part of the color filter substrate, the reverse electrode of the photodiode is connected to the gate line or the data line through a connection medium, and the forward electrode is connected to a low voltage terminal.

The gate line is configured to provide a scan signal for the thin film transistor, and the data line is configured to provide a data signal for the thin film transistor. The structure of the photodiode may refer to the structure in FIG. 2 in the first embodiment. The connection medium connecting the reverse electrode of the photodiode with the gate line or the data line may be a gold ball or a silver ball, thereby realizing power supply to the photodiode and utilizing a weak current generated by the photo-generated carriers of the photodiode to assist operations of the gate line and the data line.

Other structures in the display panel of this embodiment are the same as those of corresponding structural layers in the first embodiment, and will not be described in detail here.

In the display panel of the present embodiment, by using electrons generated by the photodiode under irradiation, the driving current is compensated for by the photo-generated carriers, thereby lowering the power consumptions of the thin film transistor and the display panel having the same and increasing the utilization ratio of the backlight. Further, the response time can be reduced, and the phenomenon that the display panel product is blackening at the end of a scanning line due to insufficient charging can be solved as well. The display panel of the present embodiment is especially suitable for the FHD liquid crystal display products.

### Third Embodiment

The present embodiment provides a display device including the display panel of any of the first and second embodiments.

The display device can be any product or component with display function such as a desktop computer, a tablet computer, a notebook computer, a mobile phone, a PDA, a GPS, an on-board display, a projection display, a camera, a digital camera, an electronic watch, a calculator, an electronic instrument, a gauge, a LCD panel, an electronic paper, a television, a monitor, a digital photo frame, a navigator, etc., which can be applied to many fields such as public display and virtual display.

It is to be understood that the above embodiments are merely exemplary embodiments for the purpose to explain the principles of the present disclosure, but the present disclosure is not limited thereto. Various modifications and improvements can be made by those skilled in the art without departing from the spirit and scope of the present disclosure. These modifications and improvements are also considered to be within the protection scope of the present disclosure.

1. A display panel having a plurality of pixel regions, a thin film transistor being disposed in a pixel region of the plurality of pixel regions, a gate line and a data line intersecting between adjacent ones of the plurality of pixel regions, wherein a photodiode is provided in at least one of an area corresponding to the thin film transistor in the pixel region, an area corresponding to the gate line, or an area corresponding to the data line, and the photodiode is electrically connected to either the gate line or the data line.

2. The display panel of claim 1, wherein the photodiode comprises a forward electrode, a P layer, an I layer, an N layer, and a reverse electrode which are sequentially stacked, the reverse electrode is connected to the gate line or the data line, and the forward electrode is connected a low voltage terminal.

3. The display panel of claim 2, wherein the display panel comprises an array substrate, the thin film transistor is provided in the array substrate, the thin film transistor comprises a gate, a gate insulating layer, an active layer, a source and a drain, the gate is connected to the gate line, and the source is connected to the data line, wherein
the photodiode is disposed under the gate, and the gate is shared as the reverse electrode of the photodiode.

4. The display panel of claim 2, wherein the display panel comprises a color filter substrate, the photodiode is provided in an area corresponding to the thin film transistor in the pixel region in at least part of the color filter substrate, the reverse electrode of the photodiode is connected to the gate line or the data line through a connection medium, and the forward electrode is connected to a low voltage terminal.

5. The display panel of claim 4, wherein the connection medium is a gold ball or a silver ball.

6. The display panel of claim 2, wherein the forward electrode is made of a transparent metal material, and the transparent metal material comprises indium tin oxide.

7. The display panel of claim 2, wherein in the photodiode, the P layer is made of a B₂H₆ doped a-Si material, the I layer is made of an a-Si material, and the N layer is made of a PH₃ doped a-Si material.

8. The display panel of claim 2, wherein the forward electrode is grounded or is not loaded with any voltage, and the reverse electrode has a same voltage potential as a voltage potential of the gate line or the data line.

9. The display panel of claim 2, wherein the display panel further comprises a backlight, and the forward electrode of the photodiode is closer to the backlight than the reverse electrode.

10. A display device, comprising the display panel of claim 1.

11. The display panel of claim 2, wherein the display panel comprises an array substrate, the thin film transistor is provided in the array substrate, the thin film transistor comprises a gate, a gate insulating layer, an active layer, a source and a drain, the gate is connected to the gate line, and the source is connected to the data line, wherein
the photodiode is disposed under the source, and the source is shared as the reverse electrode of the photodiode.

12. The display device of claim 10, wherein the photodiode comprises a forward electrode, a P layer, an I layer, an N layer, and a reverse electrode which are sequentially stacked, the reverse electrode is connected to the gate line or the data line, and the forward electrode is connected a low voltage terminal.

13. The display device of claim 12, wherein the display panel comprises an array substrate, the thin film transistor is provided in the array substrate, the thin film transistor comprises a gate, a gate insulating layer, an active layer, a source and a drain, the gate is connected to the gate line, and the source is connected to the data line, wherein
the photodiode is disposed under the gate, and the gate is shared as the reverse electrode of the photodiode.

14. The display device of claim 12, wherein the display panel comprises a color filter substrate, the photodiode is provided in an area corresponding to the thin film transistor in the pixel region in at least part of the color filter substrate, the reverse electrode of the photodiode is connected to the gate line or the data line through a connection medium, and the forward electrode is connected to a low voltage terminal.

15. The display device of claim 14, wherein the connection medium is a gold ball or a silver ball.

16. The display device of claim 12, wherein the forward electrode is made of a transparent metal material, and the transparent metal material comprises indium tin oxide.

17. The display device of claim 12, wherein in the photodiode, the P layer is made of a B₂H₆ doped a-Si material, the I layer is made of an a-Si material, and the N layer is made of a PH₃ doped a-Si material.

18. The display device of claim 12, wherein the forward electrode is grounded or is not loaded with any voltage, and the reverse electrode has a same voltage potential as a voltage potential of the gate line or the data line.

19. The display device of claim 12, wherein the display panel further comprises a backlight, and the forward electrode of the photodiode is closer to the backlight than the reverse electrode.

20. The display device of claim 12, wherein the display panel comprises an array substrate, the thin film transistor is provided in the array substrate, the thin film transistor comprises a gate, a gate insulating layer, an active layer, a source and a drain, the gate is connected to the gate line, and the source is connected to the data line, wherein
the photodiode is disposed under the source, and the source is shared as the reverse electrode of the photodiode.
